(19) United States
(12) Patent Application Publication
(10) Pub. No.: US 2010/0215854 A1
(43) Pub. Date: Aug. 26, 2010

(54) HVPE SHOWERHEAD DESIGN

(76) Inventors: Brian H. Burrows, San Jose, CA (US); Alexander Tam, Union City, CA (US); Ronald Stevens, San Ramon, CA (US); Jacob Grayson, Santa Clara, CA (US); Kenric T. Choi, Santa Clara, CA (US); Sumedh Acharya, Santa Clara, CA (US); Sandeep Nijhawan, Los Altos, CA (US); Olga Kryliouk, Santa Clara, CA (US); Yuriy Melnik, Santa Clara, CA (US)

Correspondence Address: PATTERSON & SHERIDAN, LLP - - APPM/TX, 3040 POST OAK BOULEVARD, SUITE 1500, HOUSTON, TX, 77056, US

(21) Appl. No.: 12/776,351

(22) Filed: May 7, 2010

Related U.S. Application Data
(63) Continuation of application No. 11/767,520, filed on Jun. 24, 2007.

(51) Int. Cl. C23C 16/455; C23C 16/00; C23C 16/08

(52) U.S. Cl. 427/255.39; 118/715; 118/725

(57) ABSTRACT

A method and apparatus that may be utilized in deposition processes, such as hydride vapor phase epitaxial (HVPE) deposition of metal nitride films, are provided. A first set of passages may introduce a metal containing precursor gas. A second set of passages may provide a nitrogen-containing precursor gas. The first and second sets of passages may be interspersed in an effort to separate the metal containing precursor gas and nitrogen-containing precursor gas until they reach a substrate. An inert gas may also be flowed down through the passages to help keep separation and limit reaction at or near the passages, thereby preventing unwanted deposition on the passages.

### CROSS-REFERENCE TO RELATED APPLICATIONS

This application is a continuation of U.S. patent application Ser. No. 11/767,520, filed Jun. 24, 2007 (Attorney Docket No. APPM/11655), which is herein incorporated by references in its entirety.

### BACKGROUND OF THE INVENTION

1. Field of the Invention

Embodiments of the present invention generally relate to the manufacture of devices, such as light emitting diodes (LEDs), and, more particularly, to a showerhead design for use in hydride vapor phase epitaxial (HVPE) deposition.

2. Description of the Related Art

Group-III nitride semiconductors are finding greater importance in the development and fabrication of a variety of semiconductor devices, such as short wavelength light emitting diodes (LEDs), laser diodes (LDs), and electronic devices including high power, high frequency, high temperature transistors and integrated circuits. One method that has been used to deposit Group-III nitrides is hydride vapor phase epitaxial (HVPE) deposition. In HVPE, a halide reacts with the Group-III metal to form a metal containing precursor (e.g., metal chloride). The metal containing precursor then reacts with a nitrogen-containing gas to form the Group-III metal nitride.

As the demand for LEDs, LDs, transistors and integrated circuits increases, the efficiency of depositing the Group-III metal nitride takes on greater importance. There is a general need for a deposition apparatus and process with a high deposition rate that can deposit films uniformly over a large substrate or multiple substrates. Additionally, uniform precursor mixing is desirable for consistent film quality over the substrate. Therefore, there is a need in the art for an improved HVPE deposition method and an HVPE apparatus.

### SUMMARY OF THE INVENTION

The present invention generally methods and apparatus for gas delivery in deposition processes, such as hydride vapor phase epitaxial (HVPE).

One embodiment provides a method of forming a metal nitride on one or more substrates. The method generally includes introducing a metal containing precursor gas through a first set of passages above the one or more substrates, introducing a nitrogen-containing precursor gas through a second set of passages above the one or more substrates, wherein the second set of passages are interspersed with the first set of passages, and introducing an inert gas above the first and second set of passages towards the one or more substrates to limit reaction of the metal containing precursor gas and nitrogen-containing precursor gas at or near the first and second set of passages.

One embodiment provides a method of forming a metal nitride on one or more substrates. The method generally includes introducing a metal containing precursor gas through a set of passages above the one or more substrates and introducing a nitrogen-containing precursor gas above the set of passages so that the nitrogen-containing precursor gas flows between the set of passages toward the one or more substrates.

One embodiment provides a gas delivery apparatus for a hydride vapor phase epitaxial chamber. The apparatus generally includes a first gas inlet coupled to a metal containing precursor gas source, a second gas inlet separate from the first gas inlet, the second gas inlet coupled to a nitrogen-containing precursor gas source, and one or more third gas inlets separate from the first and second gas inlets, the third gas inlet oriented to direct gas into the chamber in a direction substantially perpendicular to the surface of at least one substrate.

One embodiment provides a gas delivery apparatus for a hydride vapor phase epitaxial chamber. The apparatus generally includes a first gas inlet coupled to a metal containing precursor gas source and a second gas inlet separate from the first gas inlet, the second gas inlet coupled with a nitrogen-containing precursor gas source, wherein the second gas inlet is oriented to direct gas into the chamber in a direction substantially perpendicular to the surface of the at least one substrate.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

FIG. 1 is a cross sectional view of a deposition chamber according to one embodiment of the invention.

FIG. 2 is a cross sectional perspective side-view of a showerhead assembly according to one embodiment of the invention.

FIG. 3 is a cross sectional top-view of a showerhead assembly according to one embodiment of the invention.

FIG. 4 is a cross sectional perspective cutaway-view of a showerhead assembly according to one embodiment of the invention.

FIGS. 5A-5B are perspective views of the gas passage components of a showerhead assembly according to one embodiment of the invention.

FIG. 6 is a perspective view of the top plate component of a showerhead assembly according to one embodiment of the invention.

FIG. 7 is a cross sectional perspective side-view of a showerhead assembly according to one embodiment of the invention.

FIGS. 8A-8C are perspective views of the boat components of a showerhead assembly according to one embodiment of the invention.

FIGS. 9A-9B are perspective views of the gas passage components of a showerhead assembly according to one embodiment of the invention.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

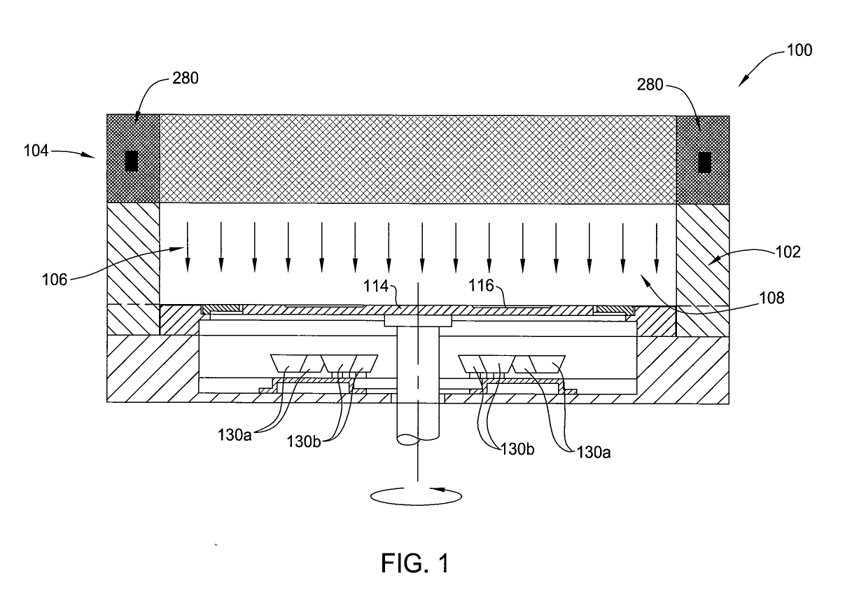

The present invention generally provides a method and apparatus that may be utilized in deposition processes, such as hydride vapor phase epitaxial (HVPE) deposition. FIG. 1 is a schematic cross sectional view of an HVPE chamber that may be used to practice the invention according to one embodiment of the invention. Exemplary chambers that may be adapted to practice the present invention are described in U.S. patent application Ser. Nos. 11/411,672 and 11/404,516, both of which are incorporated by reference in their entireties.

The apparatus 100 in FIG. 1 includes a chamber body 102 that encloses a processing volume 108. A showerhead assembly 104 is disposed at one end of the processing volume 108, and a substrate carrier 114 is disposed at the other end of the processing volume 108. The substrate carrier 114 may include one or more recesses 116 within which one or more substrates may be disposed during processing. The substrate carrier 114 may carry six or more substrates. In one embodiment, the substrate carrier 114 carries eight substrates. It is to be understood that more or less substrates may be carried on the substrate carrier 114. Typical substrates may be sapphire, SiC or silicon. Substrate size may range from 50 mm-100 mm in diameter or larger. The substrate carrier size may range from 200 mm-500 mm. The substrate carrier may be formed from a variety of materials, including SiC or SiC-coated graphite. It is to be understood that the substrates may consist of sapphire, SiC, GaN, silicon, quartz, GaAs, AlN or glass. It is to be understood that substrates of other sizes may be processed within the apparatus 100 and according to the processes described herein. The showerhead assembly, as described above, may allow for more uniform deposition across a greater number of substrates or larger substrates than in traditional HVPE chambers, thereby reducing production costs. The substrate carrier 114 may rotate about its central axis during processing. In one embodiment, the substrates may be individually rotated within the substrate carrier 114.

The substrate carrier 114 may be rotated. In one embodiment, the substrate carrier 114 may be rotated at about 2 RPM to about 100 RPM. In another embodiment, the substrate carrier 114 may be rotated at about 30 RPM. Rotating the substrate carrier 114 aids in providing uniform exposure of the processing gases to each substrate.

A plurality of lamps 130a, 130b may be disposed below the substrate carrier 114. For many applications, a typical lamp arrangement may comprise banks of lamps above (not shown) and below (as shown) the substrate. One embodiment may incorporate lamps from the sides. In certain embodiments, the lamps may be arranged in concentric circles. For example, the inner array of lamps 130b may include eight lamps, and the outer array of lamps 130a may include twelve lamps. In one embodiment of the invention, the lamps 130a, 130b are each individually powered. In another embodiment, arrays of lamps 130a, 130b may be positioned above or within showerhead assembly 104. It is understood that other arrangements and other numbers of lamps are possible. The arrays of lamps 130a, 130b may be selectively powered to heat the inner and outer areas of the substrate carrier 114. In one embodiment, the lamps 130a, 130b are collectively powered as inner and outer arrays in which the top and bottom arrays are either collectively powered or separately powered. In yet another embodiment, separate lamps or heating elements may be positioned over and/or under the source boat 280. It is to be understood that the invention is not restricted to the use of arrays of lamps. Any suitable heating source may be utilized to ensure that the proper temperature is adequately applied to the processing chamber, substrates therein, and a metal source. For example, it is contemplated that a rapid thermal processing lamp system may be utilized such as is described in United States Patent Publication No. 2006/0018639 A1, which is incorporated by reference in its entirety.

One or more lamps 103a, 130b may be powered to heat the substrates as well as the source boat 280. The lamps may heat the substrate to a temperature of about 900 degrees Celsius to about 1200 degrees Celsius. In another embodiment, the lamps 130a, 130b maintain the metal source in well 820 within the source boat 280 at a temperature of about 350 degrees Celsius to about 900 degrees Celsius. A thermocouple may be positioned within the well 820 to measure the metal source temperature during processing. The temperature measured by the thermocouple may be fed back to a controller that adjusts the heat provided from the heating lamps 130a, 130b so that the temperature of the metal source in well 820 may be controlled or adjusted as necessary.

During the process according to one embodiment of the invention, precursor gases 106 flow from the showerhead assembly 104 towards the substrate surface. Reaction of the precursor gases 106 at or near the substrate surface may deposit various metal nitride layers upon the substrate, including GaN, AlN, and InN. Multiple metals may also be utilized for the deposition of “combination films” such as AlGaN and/or InGaN. The processing volume 108 may be maintained at a pressure of about 760 Torr down to about 100 Torr. In one embodiment, the processing volume 108 is maintaining at a pressure of about 450 Torr to about 760 Torr.

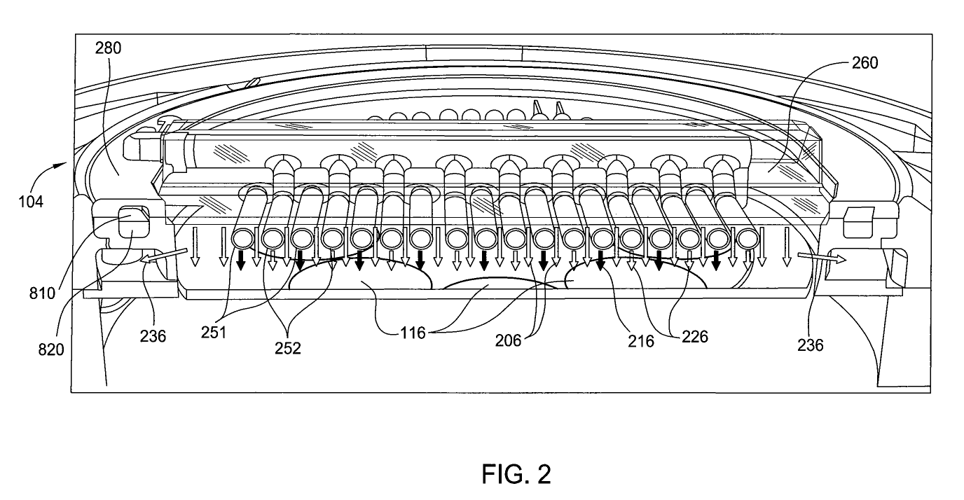

FIG. 2 is a cross sectional perspective of the HVPE chamber of FIG. 1, according to one embodiment of the invention. A source boat 280 encircles the chamber body 102. A metal source fills the well 820 of the source boat 280. In one embodiment, the metal source includes any suitable metal source, such as gallium, aluminum, or indium, with the particular metal selected based on the particular application needs. A halide or halogen gas flows through channel 810 above the metal source in well 820 of the source boat 280 and reacts with the metal source to form a gaseous metal-containing precursor. In one embodiment, HCl reacts with liquid gallium to form gaseous GaCl. In another embodiment, Cl2 reacts with liquid gallium to form GaCl and GaCl3. Additional embodiments of the invention utilize other halides or halogens to attain a metal-containing gas phase precursor. Suitable hydrides include those with composition HX (e.g., with X═Cl, Br, and I) and suitable halogens include Cl₂, Br, and I₂. For halides, the unbalanced reaction equation is:

HX (gas)+M (liquid metal)->MX (gas)+H (gas)

where X═Cl, Br, or I and M=Ga, Al, or In. For halogens the equation is:

Z (gas)+M (liquid metal)->MZ (gas)

where Z═Cl₂, Br, I₂ and M=Ga,Al,In. Hereafter the gaseous metal containing specie will be referred to as the “metal containing precursor” (e.g., metal chloride).

The metal containing precursor gas 216 from the reaction within the source boat 280 is introduced into the processing volume 108 through a first set of gas passages, such as tubes 251. It is to be understood that metal containing precursor gas 216 may be generated from sources other than source boat 280. A nitrogen-containing gas 226 may be introduced into the processing volume 108 through a second set of gas passages, such as tubes 252. While an arrangement of tubes are shown as an example of a suitable gas distribution structure and may be utilized in some embodiments, a variety of other types of arrangements of different type passages designed to provide gas distribution as described herein may also be utilized for other embodiments. Examples of such an arrangement of passages include a gas distribution structure having (as passages) gas distribution channels formed in a plate, as described in greater detail below.

In one embodiment, the nitrogen-containing gas includes ammonia. The metal containing precursor gas 216 and the nitrogen-containing gas 226 may react near or at the surface of the substrate, and a metal nitride may be deposited onto the substrates. The metal nitride may deposit on the substrates at a rate of about 1 microns per hour to about 60 microns per hour. In one embodiment, the deposition rate is about 15 microns per hour to about 25 microns per hour.

In one embodiment, an inert gas 206 is introduced into the processing volume 108 through plate 260. By flowing inert gas 206 between the metal containing precursor gas 216 and the nitrogen-containing gas 226, the metal containing precursor gas 216 and the nitrogen-containing gas 226 may not contact each other and prematurely react to deposit on undesired surfaces. In one embodiment, the inert gas 206 includes hydrogen, nitrogen, helium, argon or combinations thereof. In another embodiment, ammonia is substituted for the inert gas 206. In one embodiment, the nitrogen-containing gas 226 is provided to the processing volume at a rate of about 1 slm to about 15 slm. In another embodiment, the nitrogen-containing gas 226 is co-flowed with a carrier gas. The carrier gas may include nitrogen gas or hydrogen gas or an inert gas. In one embodiment, the nitrogen-containing gas 226 is co-flowed with a carrier gas which may be provided at a flow rate of about 0 slm to about 15 slm. Typical flowrates for halide or halogen are 5-1000 sccm but may include flowrates up to 5 slm. Carrier gas for the halide/halogen gas may be 0.1-10 μm and comprises the inert gases listed previously. Additional dilution of the halide/halogen/carrier gas mixture may occur with an inert gas from 0-10 slm. Flow rates for inert gas 206 are 5-40 slm. Process pressure varies between 100-1000 torr. Typical substrate temperatures are 500-120° C.

The inert gas 206, metal containing precursor gas 216, and the nitrogen-containing gas 226 may exit the processing volume 108 through exhausts 236, which may be distributed about the circumference of the processing volume 108. Such a distribution of exhausts 236 may provide for uniform flow of gases across the surface of the substrate.

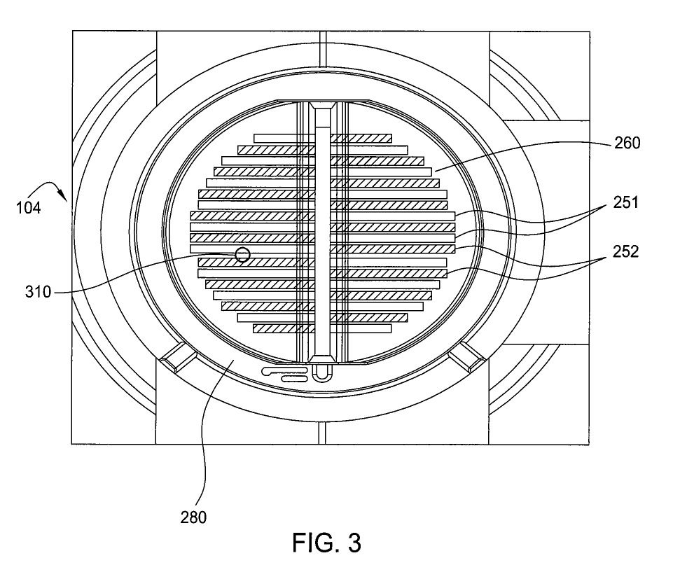

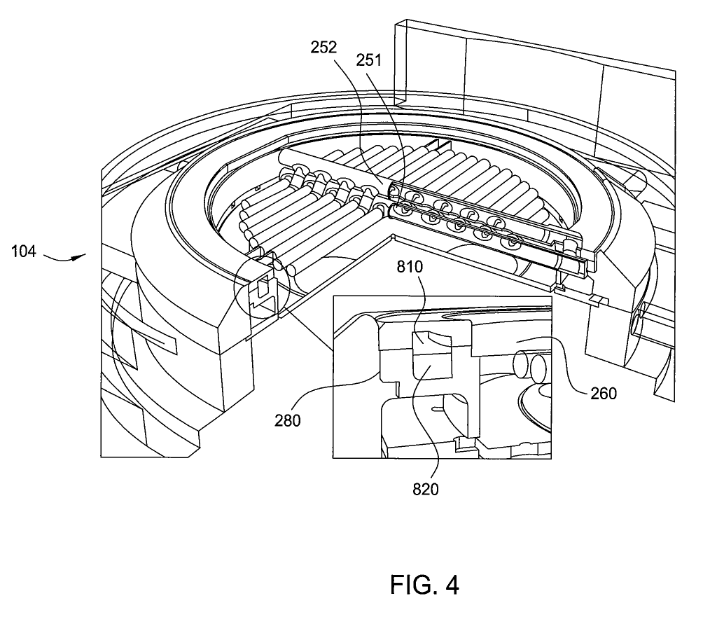

As shown in FIGS. 3 and 4, the gas tubes 251 and gas tubes 252 may be interspersed, according to one embodiment of the invention. The flow rate of the metal containing precursor gas 216 within gas tubes 251 may be controlled independently of the flow rate of the nitrogen-containing gas 226 within gas tubes 252. Independently controlled, interspersed gas tubes may contribute to greater uniformity of distribution of each of the gases across the surface of the substrate, which may provide for greater deposition uniformity.

Additionally, the extent of the reaction between metal containing precursor gas 216 and nitrogen-containing gas 226 will depend on the time the two gases are in contact. By positioning gas tubes 251 and gas tubes 252 parallel to the surface of the substrate, metal containing precursor gas 216 and nitrogen-containing gas 226 will come into contact simultaneously at points equidistant from gas tubes 251 and gas tubes 252, and will therefore react to generally the same extent at all points on the surface of the substrate. Consequently, deposition uniformity can be achieved with substrates of larger diameters. It should be appreciated that variation of distance between the surface of the substrate and gas tubes 251 and gas tubes 252 will govern the extent to which metal containing precursor gas 216 and nitrogen-containing gas 226 will react. Therefore, according to one embodiment of the invention, this dimension of the processing volume 108 may be varied during the deposition process. Also, according to another embodiment of the invention, the distance between gas tubes 251 and the surface of the substrate may be different from the distance between gas tubes 252 and the surface of the substrate. In addition, separation between the gas tubes 251 and 252 may also prevent reaction between the metal containing and nitrogen-containing precursor gases and unwanted deposition at or near the tubes 251 and 252. As will be described below, an inert gas may also be flowed between the tubes 251 and 252 to help maintain separation between the precursor gases.

In one embodiment of the invention, a metrology viewport 310 may be formed in plate 260. This may provide access for radiation measurement instruments to processing volume 108 during processing. Such measurements may be made by an interferometer to determine the rate at which a film is depositing on a substrate by comparing reflected wavelength to transmitted wavelength. Measurements may also be made by a pyrometer to measure substrate temperature. It should be appreciate that metrology viewport 310 may provide access to any radiation measurement instruments commonly used in conjunction with HVPE.

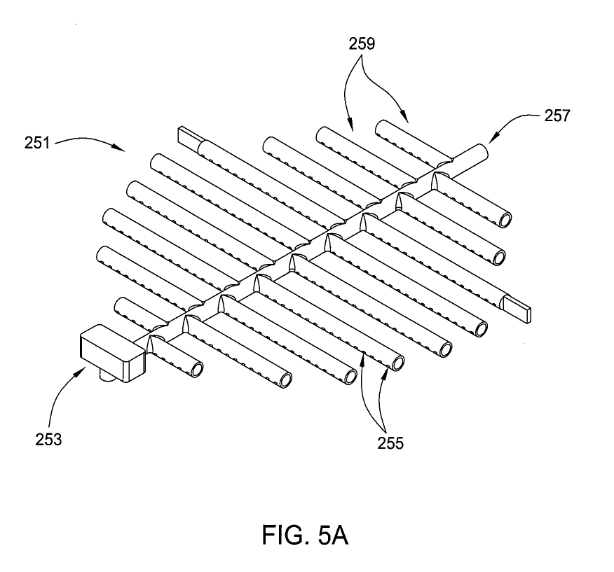

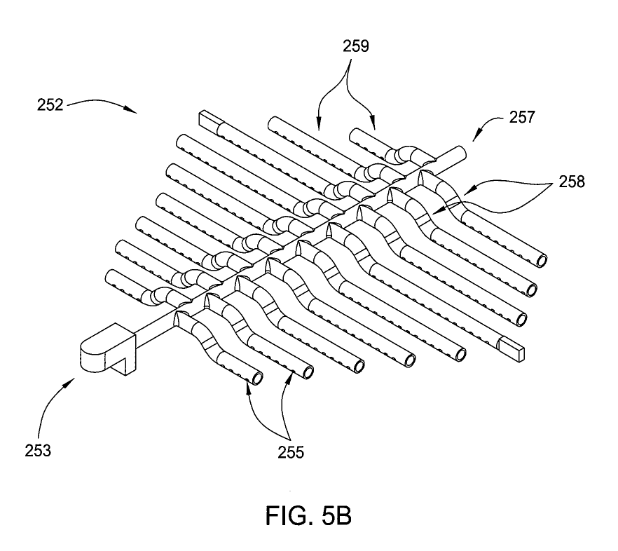

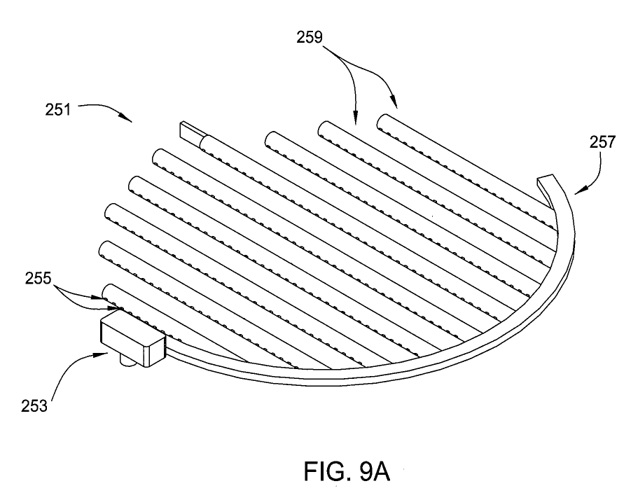

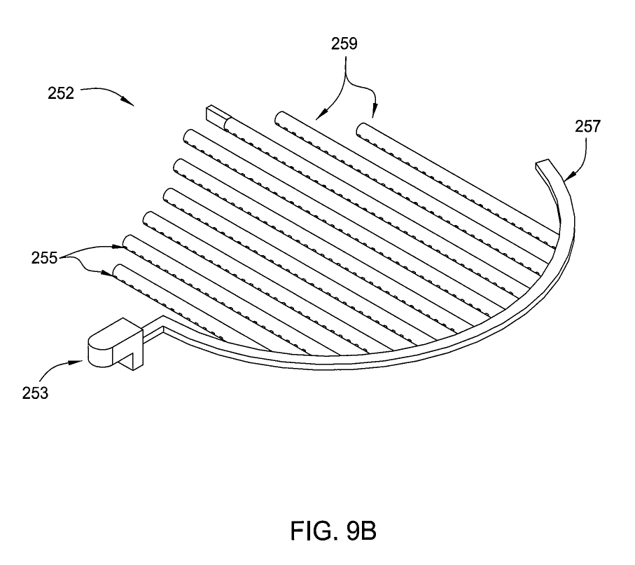

Interspersing of gas tubes 251 and gas tubes 252 may be achieved by constructing the tubes as shown in FIG. 5, according to one embodiment of the invention. Each set of tubes may essentially include a connection port 253, connected to a single trunk tube 257, which is also connected to multiple branch tubes 259. Each of the branch tubes 259 may have multiple gas ports 255 formed on the side of the tubes which generally faces the substrate carrier 114. The connection port 253 of gas tubes 251 may be constructed to be positioned between the connection port 253 of gas tubes 252 and the processing volume 108. The trunk tube 257 of gas tubes 251 would then be positioned between the trunk tube 257 of gas tubes 252 and the processing volume 108. Each branch tube 259 of gas tube 252 may contain an “S” bend 258 close to the connection with trunk tube 257 so that the length of the branch tubes 259 of gas tubes 252 would be parallel to, and aligned with, branch tubes 259 of gas tubes 251. Similarly, interspersing of gas tubes 251 and gas tubes 252 may be achieved by constructing the tubes as shown in FIG. 9, according to another embodiment of the invention which is discussed below. It is to be understood that the number of branch tubes 259, and, consequently, the spacing between adjacent branch tubes, may vary. Larger distances between adjacent branch tubes 259 may reduce premature deposition on the surface of the tubes. Premature deposition may also be reduced by adding partitions between adjacent tubes. The partitions may be positioned perpendicular to the surface of the substrate, or the partitions may be angled so as to direct the gas flows. In one embodiment of the invention, the gas ports 255 may be formed to direct metal containing precursor gas 216 at an angle to nitrogen-containing gas 226.

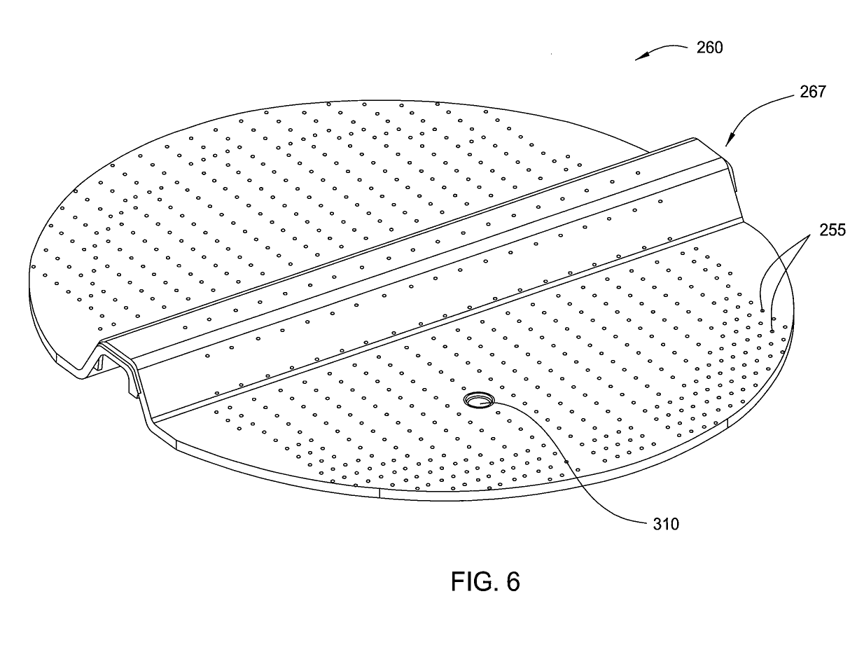

FIG. 6 shows plate 260, according to one embodiment of the invention. As previously described, inert gas 206 may be introduced into the processing volume 108 through multiple gas ports 255 distributed across the surface of plate 260. Notch 267 of plate 260 accommodates the positioning of trunk tube 257 of gas tubes 252, according to one embodiment of the invention. Inert gas 206 may flow between the branch tubes 259 of gas tubes 251 and gas tubes 252, thereby maintaining separation of the flow of metal containing precursor gas 216 from nitrogen-containing gas 226 until the gases approach the surface of the substrate, according to one embodiment of the invention.

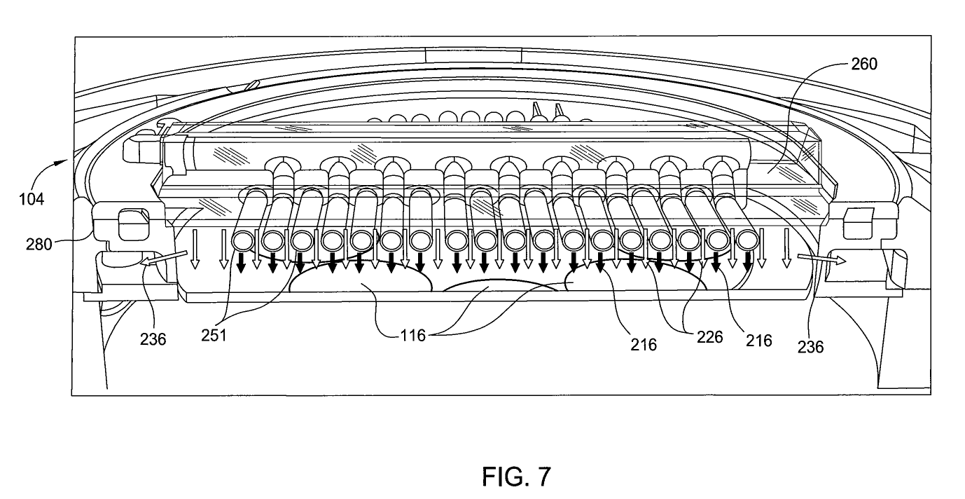

According to one embodiment of the invention, shown in FIG. 7, nitrogen-containing gas 226 may be introduced into processing volume 108 through plate 260. According to this embodiment, branch tubes 259 of gas tubes 252 are replaced by additional branch tubes 259 of gas tube 251. Metal containing precursor gas may thereby be introduced into processing volume 108 through gas tubes 252.

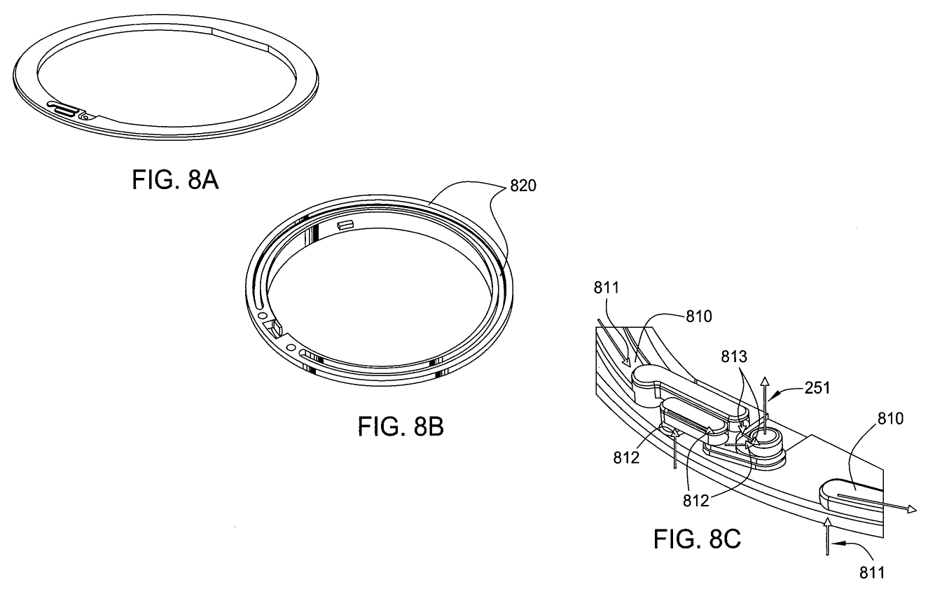

FIG. 8 shows the components of the source boat 280, according to one embodiment of the invention. The boat may be made up of a top portion (FIG. 8A) which covers a bottom portion (FIG. 8B). Joining the two portions creates an annular cavity made up of a channel 810 above a well 820. As previously discussed, chlorine containing gas 811 may flow through the channel 810 and may react with a metal source in the well 820 to produce a metal containing precursor gas 813. According to one embodiment of the invention, metal containing precursor gas 813 may be introduced through gas tubes 251 into processing volume 108 as the metal containing precursor gas 216.

In another embodiment of the invention, metal containing precursor gas 813 may be diluted with inert gas 812 in the dilution port shown in FIG. 8C. Alternatively, inert gas 812 may be added to chlorine containing gas 811 prior to entering channel 810. Additionally, both dilutions may occur; that is, inert gas 812 may be added to chlorine containing gas 811 prior to entering channel 810, and additional inert gas 812 may be added at the exit of channel 810. The diluted metal containing precursor gas is then introduced through gas tubes 251 into processing volume 108 as the metal containing precursor gas 216. The residence time of the chlorine containing gas 811 over the metal source will be directly proportional to the length of the channel 810. Longer residence times generate greater conversion efficiency of the metal containing precursor gas 216. Therefore, by encircling chamber body 102 with source boat 280, a longer channel 810 can be created, resulting in greater conversion efficiency of the metal containing precursor gas 216. A typical diameter of top portion (FIG. 8A) or bottom portion (FIG. 8B), which make up channel 810, is in the range of 10-12 inches. The length of channel 810 is the circumference of top portion (FIG. 8A) and bottom portion (FIG. 8B) and is in the range of 30-40 inches.

FIG. 9 shows another embodiment of the invention. In this embodiment, trunk tubes 257 of gas tubes 251 and 252 may be reconfigured to follow the perimeter of processing volume 108. By moving the trunk tubes 257 to the perimeter, the density of gas ports 255 may become more uniform across the surface of the substrate. It is to be understood that other configurations of trunk tubes 257 and branch tubes 259, with complimentary reconfigurations of plate 260, are possible.

Those skilled in the art will recognize that a variety of modifications may be made from the embodiments described above, while still staying within the scope of the present invention. As an example, as an alternative (or in addition) to an internal boat, some embodiments may utilize a boat that is located outside the chamber. For some such embodiments, a separate heating source and/or heated gas lines may be used to deliver precursor from the external boat to the chamber.

For some embodiments, some type of mechanism may be utilized to all a boat located within a chamber to be refilled (e.g., with liquid metal) without opening the chamber. For example, some type of apparatus utilizing an injector and plunger (e.g., similar to a large-scale syringe) may be located above the boat so that the boat can be refilled with liquid metal without opening the chamber.

For some embodiments, an internal boat may be filled from an external large crucible that is connected to the internal boat. Such a crucible may be heated (e.g., resistively or via lamps) with a separate heating and temperature control system. The crucible may be used to “feed” the boat by various techniques, such as a batch process where an operator opens and closes manual valves, or through the use of process control electronics and mass flow controllers.

For some embodiments, a flash vaporization technique may be utilized to deliver metal precursors into the chamber. For example, flash vaporize metal precursor may be delivered via a liquid injector to inject small amounts of metal into the gas stream.

For some embodiments, some form of temperature control may be utilized to maintain precursor gases in an optimal operating temperature. For example, a boat (whether internal or external) may be fitted with a temperature sensor (e.g., a thermocouple) in direct contact to determine temperature of the precursor in the boat. This temperature sensor may be connected with an automatic feedback temperature control. As an alternative to a directly contacting temperature sensor, remote pyrometry may be utilized to monitor boat temperature.

For an external boat design, a variety of different types of showerhead designs (such as those described above and below) may be utilized. Such showerheads may be constructed from suitable material that can withstand extreme temperatures (e.g., up to 1000° C.) such as SiC or quartz or SiC-coated graphite. As described above, tube temperature may be monitored via thermocouples or remote pyrometry.

For some embodiments, banks of lamps located from top and bottom of chamber may be tuned to adjust tube temperature as necessary to accomplish a variety of goals. Such goals may include minimizing deposition on tubes, maintaining a constant temperature during the deposition process, and ensuring a maximum temperature bound is not exceeded (in order to minimize damage due to thermal stresses).

The components shown in FIGS. 5A-B, 6, 8A-C, and 9A-B may be constructed from any suitable materials, such as SiC, SiC-coated graphite, and/or quartz and may have any suitable physical dimensions. For example, for some embodiments, the showerhead tubes shown in FIGS. 5A-B and 9A-B may have a wall thickness in a range of 1-10 mm (e.g., 2 mm in some applications).

The tubes may also be constructed in a manner that prevents damage from chemical etching and/or corrosion. For example, the tubes may include some type of coating, such as SiC or some other suitable coating that minimizes damage from chemical etching and corrosion. As an alternative, or in addition, the tubes may be surrounded by a separate part that shields the tubes from etching and corrosion. For some embodiments, a main (e.g., center) tube may be quartz while branch tubes may be SiC.

In some applications, there may be a risk of deposits forming on the tubes, which may impede performance, for example, by clogging gas ports. For some embodiments, to prevent or minimize deposition, some type of barrier (e.g., baffles or plates) may be placed between the tubes. Such barriers may be designed to be removable and easily replaceable, thereby facilitating maintenance and repair.

While showerhead designs utilizing branch tubes have been described herein, for some embodiments, the tube construction may be replaced with a different type of construction designed to achieve a similar function. As an example, for some embodiments, delivery channels and holes may be drilled into a single-piece plate that provides a similar function as the tubes in terms of gas separation and delivery into the main chamber. As an alternative, rather than a single piece, a distribution plate may be constructed via multiple parts that can be fit together or assembled in some way (e.g., bonded, welded or braised).

For other embodiments, solid graphite tubes may be formed, coated with SiC, and the graphite may be subsequently removed to leave a series of channels and holes. For some embodiments showerheads may be constructed with various shaped (e.g., elliptical, round, rectangular, or square) clear or opaque quartz plates with holes formed therein. Suitably dimensioned tubing (e.g., channels having 2 mm ID×4 mm OD) may be fused to the plates for gas delivery.

For some embodiments, various components may be made of dissimilar materials. In such cases, measures may be taken in an effort to ensure components fit securely and prevent gas leakage. As an example, for some embodiments, a collar may be used to securely fit a quartz tube into a metal part in order to prevent gas leakage. Such collars may be made of any suitable material, for example, that allows for thermal expansion differences of the dissimilar parts that causes the parts to expand and contract by different amounts, which might otherwise cause damage to the parts or gas leakage.

As described above (e.g., with reference to FIG. 2), halide and halogen gases may be utilized in a deposition process. In addition, the aforementioned halides and halogens may be utilized as etchant gases for in-situ cleaning of the reactor. Such a cleaning process may involve flowing a halide or halogen gas (either with or without an inert carrier gas) into the chamber. At temperatures from 100-1200° C., etchant gases may remove deposition from reactor walls and surfaces. Flow rates of enchant gases vary from 1-20 slm and flow rates of inert carrier gases vary from 0-20 slm. Corresponding pressures may vary from 100-1000 torr and chamber temperature may vary from 20-120° C.

Further, the aforementioned halide and halogen gases may be utilized in a pretreatment process of substrates, for example, to promote high-quality film growth. One embodiment may involve flowing a halide or halogen gas into the chamber through tubes 251 or through plate 260 without flowing through the boat 280. Inert carrier and/or dilution gases may combine with the halide or halogen gas. Simultaneously NH₃ or similar nitrogen containing precursor may flow through tubes 252. Another embodiment of the pretreatment may consist of flowing only a nitrogen-containing precursor with or without inert gases. Additional embodiments may consist of a series of two or more discrete steps, each of which may be different with respect to duration, gases, flowrates, temperature and pressure. Typical flow rates for halide or halogen are 50-1000 sccm but may include flow rates up to 5 slm. Carrier gas for the halide/halogen gas may be 1-40 slm and comprises inert gases listed previously. Additional dilution of the halide/halogen/carrier gas mixture may occur with an inert gas from 0-10 slm. The flowrate of NH₃ is between 1-30 slm and is typically greater than the etchant gas flowrate. Process pressure may vary between 100-1000 torr. Typical substrate temperatures are in a range of 500-1200° C.

In addition, Cl2 plasma may be generated for cleaning/deposition processes. Further, chambers described herein may be implemented as part of a multi-chamber system described in co-pending U.S. patent application Ser. No. 11/404,516, which is herein incorporated by reference in its entirety. As described therein, a remote plasma generator may be included as part of the chamber hardware, which can be utilized in the HVPE chamber described herein. Gas lines and process control hardware/software for both deposition and cleaning processes described in the application may also apply to the HVPE chamber described herein. For some embodiments, chlorine-containing gas or plasma may be delivered from above a top plate, such as that shown in FIG. 6, or delivered through tubes that deliver a Ga-containing precursor. The type of plasma that could be utilized is not limited exclusively to chlorine, but may include flourine, iodine, bromine. The source gases used to generate plasma may be halogens, such as Cl₂, Br, I₂, or may be gases that contain group 7A elements, such as NF₃.

While the foregoing is directed to embodiments of the present invention, other and further embodiments of the invention may be devised without departing from the basic scope thereof, and the scope thereof is determined by the claims that follow.

1. A method of forming a metal nitride layer on one or more substrates, comprising:
exposing a metal source to a first processing gas comprising chlorine (Cl₂) to form a metal halide gas, wherein the metal source comprises an element selected from the group consisting of gallium, aluminum and indium; and
exposing one or more substrates to a nitrogen precursor gas and the metal halide gas to form a metal nitride layer on a surface of the one or more substrates.

2. The method of claim 1, wherein the metal source comprises gallium.

3. The method of claim 2, wherein the gallium is heated to a temperature of between about 350° C. and 900° C. before exposing the metal source to the first processing gas.

4. The method of claim 3, wherein exposing the one or more substrates to the metal halide gas and nitrogen precursor gas further comprises heating the one or more substrates to a temperature between about 900° C. and about 1200° C. and establishing a pressure between about 100 Torr and about 760 Torr in a processing volume in which the one or more substrates are disposed.

5. The method of claim 1, further comprising:
exposing another metal source to a second processing gas comprising chlorine (Cl₂) to form another metal halide gas, wherein the another metal source comprises an element selected from the group consisting of gallium, aluminum and indium, and the element from which the metal source and the element from which the another metal source each comprise are different; and
the exposing one or more substrates to a nitrogen precursor gas and the metal halide gas further comprises exposing one or more substrates to a nitrogen precursor gas, the metal halide gas and the another metal halide gas to form the metal nitride layer on the surface of the one or more substrates.

6. The method of claim 1, wherein the nitrogen precursor gas comprises ammonia.

7. The method of claim 1, further comprising exposing the one or more substrates to a pretreatment gas comprising chlorine (Cl₂) during a pretreatment process prior to forming the metal nitride layer.

8. The method of claim 7, wherein the pretreatment gas further comprises gallium chloride or ammonia.

9. The method of claim 1, further comprising exposing the one or more substrates to a pretreatment gas comprising ammonia during a pretreatment process prior to forming the metal nitride layer.

10. The method of claim 1, wherein the one or more substrates comprises a material selected from a group consisting of sapphire, silicon and aluminum nitride.

11. The method of claim 1, wherein the one or more substrates comprise two or more substrates, and said exposing the two or more substrates to the metal halide gas and the nitrogen precursor gas to form the metal nitride layer further comprises rotating the two or more substrates at between about 2 rpm and about 100 rpm.

12. The method of claim 1, wherein the exposing one or more substrates further comprises:
delivering the metal halide gas to the surface of the one or more substrates using a precursor gas distribution structure, and
delivering the nitrogen precursor gas to the surface of the one or more substrates using a nitrogen precursor gas distribution structure.

13. The method of claim 12, wherein the nitrogen precursor gas distribution structure is disposed a distance from the surface of the one or more substrates and is configured to direct the nitrogen precursor gas towards the one or more substrates, and the precursor gas distribution structure is disposed between the nitrogen precursor gas distribution structure and the surface of the one or more substrates.

14. A method of forming a metal nitride containing layer on one or more substrates, comprising:
exposing an aluminum source to a first processing gas comprising chlorine (Cl₂) to form a metal precursor gas;
exposing one or more substrates disposed within a processing volume in a processing chamber to a portion of the formed metal precursor gas and a nitrogen precursor gas to form an aluminum nitride containing layer on the one or more substrates;
exposing a liquid gallium source to a second processing gas comprising chlorine (Cl₂) to form a gallium precursor gas; and
exposing the one or more substrates to a portion of the formed gallium precursor gas and a nitrogen precursor gas to form a gallium nitride containing layer on the one or more substrates.

15. The method of claim 14, wherein the aluminum nitride containing layer and the gallium nitride containing layer are formed in the same processing chamber.

16. A method for forming a metal nitride layer on one or more substrates, comprising:
exposing one or more substrates and a surface of a chamber component that are disposed in a processing volume of a deposition chamber to a metal halide gas and a nitrogen precursor gas to form a gallium nitride containing layer on the one or more substrates;
removing the one more substrates from the processing volume; and
exposing the chamber component to a cleaning gas that comprises a halogen gas, wherein the cleaning gas is adapted to remove at least a portion of the metal nitride layer formed on the chamber component.

17. The method of claim 16, wherein the halogen gas comprises a chlorine (Cl₂) gas or a fluorine (F₂) gas.

18. The method of claim 16, wherein exposing the chamber component to a cleaning gas further comprises heating the chamber component to a temperature between about 100° C. and about 1200° C.

19. The method of claim 18, wherein heating the chamber component comprises delivering energy to the chamber component from one or more lamps.

20. The method of claim 16, wherein the chamber component comprises a top plate having a plurality of ports formed therein that are configured to receive the cleaning gas from a cleaning gas source and deliver the cleaning gas to the processing volume of the deposition chamber.

21. The method of claim 16, further comprising:
delivering the cleaning gas to the processing volume through a first gas distribution structure; and
delivering a metal halide gas to the processing volume through a second gas distribution structure during the forming of the metal nitride layer.

22. The method of claim 21, wherein the first gas distribution structure is disposed a distance from the surface of the one or more substrates, and the second gas distribution structure is disposed between the first gas distribution structure and the surface of the one or more substrates.

23. The method of claim 16, further comprising adding energy to the cleaning gas using a plasma prior to exposing the chamber component to the cleaning gas.

24. A substrate processing chamber configured to deposit a metal nitride layer on one or more substrates, comprising:
a processing chamber defining a processing volume in which one or more substrates are disposed during the deposition of the metal nitride layer;
a liquid metal source boat having a cavity that is configured to retain a liquid metal, wherein the cavity is in fluid communication with the processing volume; and
a halogen gas source that is in fluid communication with the cavity, wherein the halogen gas source is configured to deliver a halogen gas to the cavity.

25. The substrate processing chamber of claim 24, wherein the halogen gas source comprises chlorine (Cl₂).

26. The substrate processing chamber of claim 25, further comprising an inert gas source coupled to the cavity, wherein the inert gas source is configured to deliver an inert gas to the cavity to cause at least a portion of the formed metal halide gas to flow into the processing volume.

27. The substrate processing chamber of claim 24, further comprising:
a first gas distribution structure that is in fluid communication with the processing volume, wherein the halogen gas source is configured to deliver a chlorine (Cl₂) gas or a fluorine (F₂) gas to the processing volume through the first gas distribution structure; and
a second gas distribution structure that is configured to deliver a metal halide gas to the processing volume, wherein the halogen gas source is configured to deliver the halogen gas to the cavity to form the metal halide gas.

28. The substrate processing chamber of claim 24, wherein the halogen gas source is in fluid communication with the processing volume, and is configured to deliver the halogen gas, which comprises chlorine (Cl₂) or fluorine (F₂), to clean a surface a chamber component disposed in the processing volume.

29. The substrate processing chamber of claim 24, wherein the halogen gas source is configured to deliver the halogen gas to clean a surface of a chamber component disposed in the processing volume, and to deliver the halogen gas to the cavity to form a metal halide gas therein, wherein the halogen gas comprises chlorine (Cl₂).

30. The substrate processing chamber of claim 24, further comprising:
one or more substrate heating elements that are configured to heat the one or more substrates to a temperature of between about 900° C. and 1200° C.

31. The substrate processing chamber of claim 30, wherein the one or more substrate heating elements are lamps.

32. The substrate processing chamber of claim 30, further comprising:
one or more liquid metal source boat heating elements configured to heat the cavity to a temperature of between about 350° C. and 900° C.

33. The substrate processing chamber of claim 24, further comprising:
a substrate carrier disposed in the processing volume, wherein the substrate carrier is configured to support the one or more substrates during the deposition of the metal nitride layer; and
one or more first heating elements that are configured to heat the substrate carrier to a temperature of between about 900° C. and 1200° C.

34. The substrate processing chamber of claim 33, further comprising:
a rotation device that is configured to rotate the substrate carrier during processing.

35. The substrate processing chamber of claim 33, wherein the substrate carrier is formed from a material that comprises SiC or graphite.

36. The substrate processing chamber of claim 24, further comprising:
a top plate having a plurality of ports formed therein that are in fluid communication with the processing volume; and
a nitrogen gas source that is configured to deliver a nitrogen-containing gas through the ports and into the processing volume.

37. The substrate processing chamber of claim 24, further comprising:
a top plate having a plurality of ports formed therein that are in fluid communication with the processing volume; and
the halogen gas source is configured to deliver the halogen gas through the ports and into the processing volume.
